(19) United States
(12) Patent Application Publication
(10) Pub. No.: US 2024/0168512 A1
(43) Pub. Date: May 23, 2024

(54) Systems and Methods for Processor Power Supply Droop Detection Schemes and Control

(71) Applicant: Intel Corporation, Santa Clara, CA (US)

(72) Inventors: Anurag Veerabathini, San Mateo, CA (US); Nazar S Haider, Fremont, CA (US)

(73) Assignee: Intel Corporation, Santa Clara, CA (US)

(21) Appl. No.: 17/988,884

(22) Filed: Nov. 17, 2022

(51) Int. Cl. G06F 1/04; H03K 5/24

(52) U.S. Cl. CPC G06F 1/04; H03K 5/24

(57) ABSTRACT

An apparatus includes a circuit to generate a clock having a period with a duty cycle less than or equal to 90%, and logic to determine a difference in an input voltage between a first time and a second time, at least in part based on the duty cycle of the clock, and to produce a first signal, at least in part based on the difference in the input voltage and a first predetermined threshold.

### BACKGROUND

### Technical Field

This disclosure relates to power supply units in computer systems and, in particular, to detecting processor power supply droop.

### Related Art

Recent advances in portable and standalone electronics and the rise of artificial-intelligence applications demand large data storage and high computational ability. These portable and standalone electronics, such as phones and laptops, have limited capability and thus use data centers to meet such a workload. Data centers contain a large number of servers containing processors powered with multi-stage power converters such as an alternating current (AC)—direct current (DC) power supply unit (PSU) and multiple DC-DC converters. High power efficiency, low cost, and small size are critical parameters for servers.

Cores in a processor are powered using an external power supply on a motherboard. FIG. 1 illustrates a power delivery network for a conventional server processor. An AC voltage VAC is converted to a DC voltage (V_{IN,MBVR}), and a motherboard voltage regulator (MBVR) further steps down to a lower DC voltage (V_{CCIN}). Additionally, a voltage regulator (VR) is implemented in the processor to convert voltage V_{CCIN} to voltage V_{VR} to power the cores.

The output of the MBVR is connected to the processor with a finite impedance path called a load-line. The load-line includes impedance from motherboard printed circuit board (PCB) metal traces, processor package pins, and metallization on the die. When a large load step is applied, the V_{CCIN} voltage drops and can reach the VR's minimum input voltage (V_{CCIN,VR,MIN}), which resets the system.

The cores switch at a high frequency to achieve high-performance computation. High-frequency switching consumes a large current. An impedance between the external power supply and the processor core thus causes the power supply voltage to drop at the core.

Typically, processors execute the events of applications in an orderly manner. When a processor executes a virus, the processor might execute many events simultaneously. When such a large application or current workload occurs, the input voltage drops significantly making the cores inoperable, and the processor might shut down.

The cores receive a minimum power supply voltage level to ensure appropriate application operation. The minimum input supply voltage should also be maintained if an additional power supply, such as a low dropout (LDO) regulator or other VR, is used between the MBVR and cores. The power converters are designed for a processor maximum workload current to prevent unintended shutdowns from happening. Each output of these power converters requires decoupling capacitances (C_{PSU}, C_{MB}, and C_{DIE}), and these capacitors are selected to meet their output voltage regulation. The MBVR is designed to support up to the virus current (IccIN_MAX), and the motherboard decoupling capacitance (C_{MB}) is chosen to limit large voltage droops.

The voltage drop is typically reduced by reducing the impedance by increasing the motherboard PCB metal trace and the on-die metallization. Additionally, the input capacitance of the processor on the package, die, and the motherboard PCB is also increased to meet the large current demand for a short duration. These methods greatly increase the area and cost of the PCB and the die.

### BRIEF DESCRIPTION OF THE SEVERAL VIEWS OF THE DRAWINGS

FIG. 1 illustrates a power delivery network for a conventional server processor.

FIG. 2 illustrates a series of input voltage (V_{CCIN}) droops received by a processor, results of a detection method for early detection of V_{CCIN} droop and corresponding current, according to an implementation of the present disclosure.

FIG. 3 illustrates a power delivery network, according to various implementations of the present disclosure.

FIG. 4 illustrates a slope detector architecture, according to an implementation of the present disclosure.

FIG. 5 illustrates a load transient detector architecture, according to an implementation of the present disclosure.

FIG. 6 illustrates an algorithm for a slope detector for throttling a processor, according to an implementation of the present disclosure.

FIG. 7 illustrates an exemplary signal chart during execution of FIG. 6.

FIG. 8 illustrates an algorithm for a slope detector for di/dt, according to an implementation of the present disclosure.

FIG. 9 illustrates an exemplary signal chart during execution of FIG. 8.

FIG. 10 illustrates an example computing system, according to an implementation of the present disclosure.

FIG. 11 is a block diagram of a register architecture 1100 according to some examples.

FIG. 12 illustrates a computing device 1200, according to an implementation of the present disclosure.

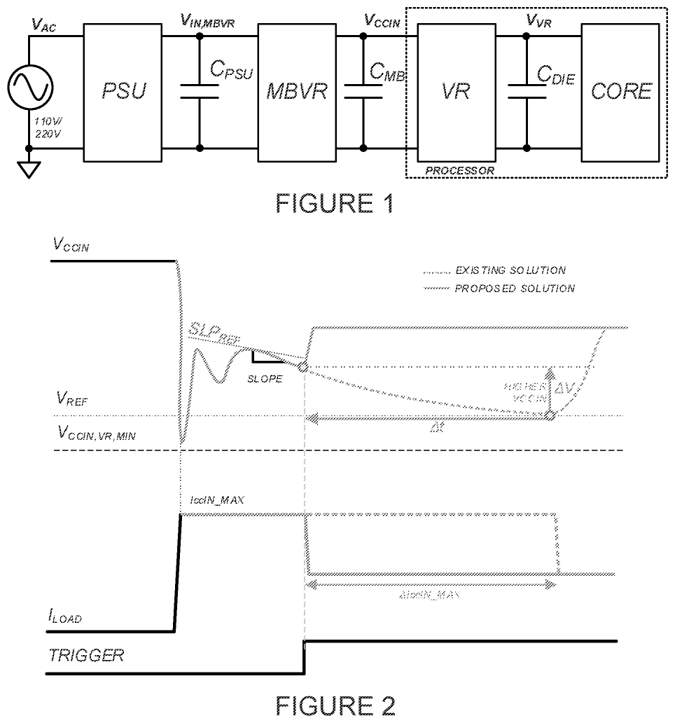

### DETAILED DESCRIPTION

For purposes of illustrating the present innovation, it might be useful to understand phenomena relevant to various implementations of the disclosure. The following foundational information can be viewed as a basis from which the present disclosure can be explained. Such information is offered for purposes of explanation only and, accordingly, should not be construed to limit the scope of the present disclosure and its potential applications.

Specifications for a processor can include a maximum worst-case voltage slope that a core can tolerate. If the slope is exceeded, then the core might not process code with the ability expected by chip customers. Such an excess slope fault could result either from the manufacturing of the chip or from the software of the chip customer. The chip manufacturer can determine from where this fault arises. However, chip customers often do not want to disclose their software to permit such a determination.

FIG. 2 illustrates a series of input voltage V_{CCIN} droops received by a processor and corresponding current. The first and second droops are troughs illustrated in solid lines, and the third droop is illustrated in a dashed line.

Conventionally, to avoid a shutdown, the voltage droop on V_{CCIN} is continuously sensed for a large drop, and the core current is reduced by scaling down its switching frequency. Existing solutions detect the V_{CCIN} DC voltage level near the third droop, and throttling is applied. Throttling is defined as a process of reducing the current consumption of the processor using one or more methods such as reducing a switching frequency, delaying computation jobs, etc. As the third droop happens after a longer duration of time spent at current IccIN_MAX, a large C_{MB} capacitance is used.

One existing solution waits for the voltage to collapse to a DC or threshold voltage level, and action is taken to reduce the core current consumption. As the action is taken after the event has happened, the motherboard and the on-die solution must support a maximum core current by maintaining the core minimum input voltage. This maintenance increases the input capacitance of the processor and increases the current requirement of the MBVR. Additionally, sizing the input capacitance becomes critical.

Programming a higher input voltage DC or threshold detection for early throttling can interfere with the real application and affect the core performance. A low-pass filter (LPF) is typically used for input voltage detection with limited bandwidth for noise immunity. So, fast voltage droops are further slowed down, causing a delayed response.

Another existing method reduces the input power supply requirements of an alternating current (AC)-DC power supply unit (PSU) and the MBVR and limits the voltage droop on the V_{CCIN} voltage input. In one such method, logic generates a throttle trigger to reduce the current consumption of the processor, which in turn reduces the voltage drop on the input. This throttling helps to limit the V_{CCIN} droop such that V_{CCIN} is greater than V_{CCIN,VR,MIN}. However, the input voltage can droop lower than the reference due to the delay associated with filtering which reduces the margin for V_{CCIN,VR,MIN} and response time.

A further existing solution supports a maximum current (IccIN_MAX) duration without collapsing the V_{CCIN} rail and avoids unintended processor shutdown during a maximum current load application. As the capacitance C_{MB} is chosen to support the difference between the maximum current and the application current, its sizing becomes crucial. A lower C_{MB} causes the input voltage of the processor to droop faster, making the filter design and comparator response time critical. Further, the input voltage can reach the VR minimum specification level before any action is taken. Using existing solutions, voltage V_{CCIN} reaches the third droop or an allowed DC detection level after spending a longer IccIN_MAX current duration.

In the proposed method, the slope of the input supply voltage is sensed. An early throttling is applied if the voltage droop rate is greater than a reference slope. The use of the slope instead of a DC or threshold level helps predict a voltage drop before the real droop event happens. Thus, the system can predict the input voltage will collapse to the third droop (lowest level) by observing the second droop behavior (mid-level). FIG. 2 illustrates such a reduction in IccIN_MAX duration and V_{CCIN} droop level limiting.

The proposed slope-detector scheme can help achieve power supply flexibility and reduce the total parasitics such as capacitances and metallization on the die, package, and on the motherboard. Further, the processor performance is greatly depends on the maximum clock frequency, which is limited by the current consumption of the core that causes the voltage drop. The ability to meet a maximum current with a reduced capacitance provides a compact and low-energy solution.

Further, the proposed slope-detector can achieve improved reliability, by detecting a failure in an input capacitance of processor that can cause the voltage to droop faster.

Implementations of the present disclosure include a system and a method to detect voltage drops at an early stage such that a minimum input voltage for the processor/core can be maintained. The supply voltage droop is detected by sensing its rate of fall using a slope-detector circuit. The frequency of the core can be reduced when the voltage droop rate is greater than the reference voltage droop slope. Reducing the core frequency reduces the processor's current consumption, which in turn reduces the voltage drop.

This detection and throttling can allow reduction in capacitance C_{MB} and allow increase in core switching frequency without fear of input supply voltage of the cores from collapsing. The detection and throttling also can reduce the cost of power delivery copper/metallization (die area), and increase processor performance and reliability. The reduced current IccIN_MAX duration and improved V_{CCIN} droop of the proposed method during the high current load step is shown in FIG. 2. The limited voltage droop can increase an input voltage margin to VR.

The proposed solution has an increased V_{CCIN,VR,MIN} margin and a reduced IccIN_MAX current duration compared to existing solutions. Some implementations of the proposed system use a sample-and-hold circuit with a reference tracking technique to compute a negative voltage slope and a comparator for decision making. The reference slope can be set by an application current drop rate.

Select implementations can perform early detection without affecting core application performance. Various implementations can detect a fast voltage droop due to a lower C_{MB} (or partially failed C_{MB}). Some implementations can use the early droop detector to reduce the input capacitance without violating droop/minimum voltage specs.

The proposed method can reduce the high current duration of the MBVR and AC-DC power supply unit (PSU) for high power application workloads. The proposed system can reduce the total decoupling capacitance at the output of the MBVR and lower the cost, area, and weight of the system. Additionally, due to a reduced voltage drop, the proposed system and methodology can allow cores to operate at a higher frequency.

The slope detection helps in projecting that voltage VCCIN is tending towards the third droop level before the voltage actually reaches the third droop level. This early detection and throttling can increase core switching frequency without voltage V_{CCIN} collapse with no extra cost of power delivery metallization.

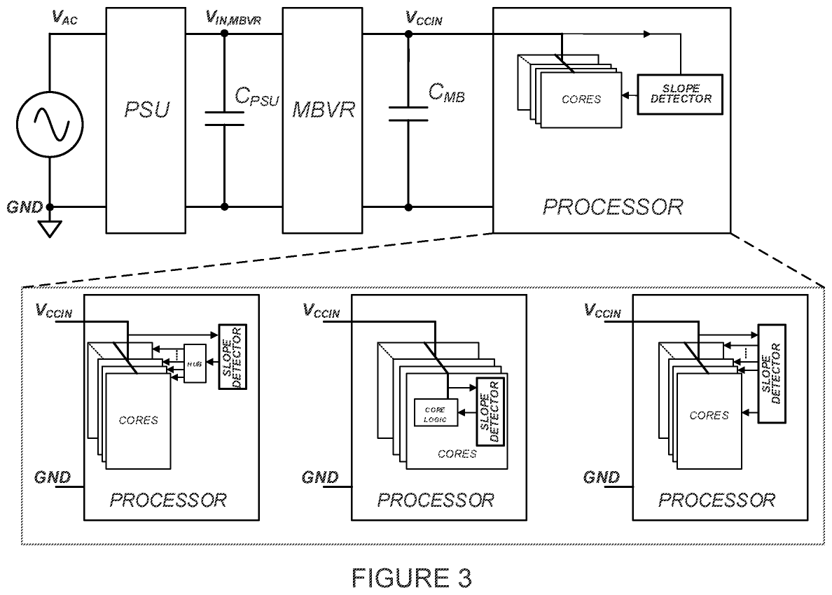

FIG. 3 illustrates a power delivery network including three alternative locations of the slope detector, according to various implementations of the present disclosure. The left implementation illustrates the slope detector inside the processor but outside the cores for overall V_{CCIN} voltage rail monitoring communicated to the cores using a central hub. The center implementation illustrates the slope detector inside the processor cores for independent core voltage rail monitoring. The right implementation illustrates the slope detector inside the processor but outside the cores for overall V_{CCIN} voltage rail monitoring without a central hub.

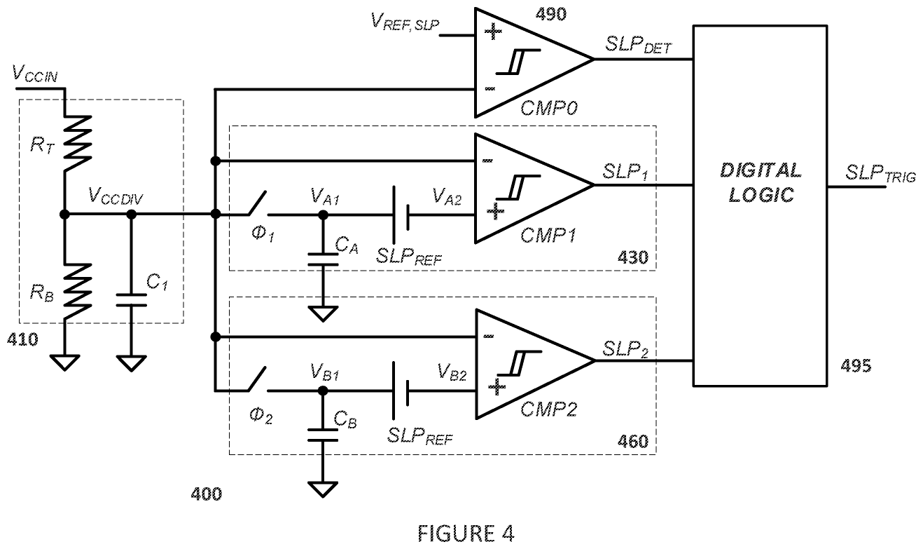

FIG. 4 illustrates architecture of a slope detector 400, according to an implementation of the present disclosure. The slope detector 400 includes a voltage divider 410, a first sample-and-hold circuit 430, a second sample-and-hold circuit 460, a comparator 490, and digital logic 495. The voltage divider 410 includes receives an input voltage V_{CCIN}, which connects to a low-side supply node via series resistors R_{T} and R_{B}. The node between the resistors is also connected to the low-side supply by a capacitor C₁ in parallel with the resistor R_{B}. The voltage at this node is V_{CCDIV}. This node is connected to inverting inputs of comparators CMP0, CMP1, and CMP2.

The first sample-and-hold circuit 43o includes comparator CMP1. The node V_{CCDIV} connects to a first end of a switch that closes based on a clock Φ1. The second end of the switch is connected to a node V_{A1}. Node V_{A1} is connected to a low-side supply node via a capacitor C_{A}. In addition, node V_{A1} is connected to the non-inverting input of comparator CMP1 via a capacitor having a value of SLP_{REF}. The non-inverting input of comparator CMP1 is labelled V_{A2}. Comparator CMP1 outputs a signal SLP₁.

The second sample-and-hold circuit 46o includes comparator CMP2. The node V_{CCDIV} connects to a first end of a switch that closes based on a clock Φ2. The second end of the switch is connected to a node V_{B1}. Node V_{B1} is connected to a low-side supply node via a capacitor C_{B}. In addition, node V_{B1} is connected to the non-inverting input of comparator CMP2 via a capacitor having a value of SLP_{REF}. The non-inverting input of comparator CMP2 is labelled V_{B2}. Comparator CMP2 outputs a signal SLP₂.

The non-inverting input of comparator CMP0 receives a reference voltage V_{REF,SLP}. The comparator CMP0 outputs a signal SLP_{DET}.

Digital logic 495 receives the signals SLP_{DET}, SLP₁, and SLP₂. The digital logic 495 outputs a throttle signal SLP_{TRIG}.

Voltage V_{CCIN} is sensed using the voltage divider in a network to generate voltage V_{CCDIV}. Two antiphase clocks ϕ₁ and ϕ₂ with programmable duty cycles and switching frequencies sample-and-hold. When a ϕ₁ switch is turned on, capacitor C_{A} is charged to V_{CCDIV}, i.e., V_{A1}=V_{CCDIV}. The inverting terminal of the CMP1 comparator continuously monitors voltage V_{CCDIV}. A delta voltage is generated at V_{A2} which is V_{A1}-SLP_{REF}, and it is connected to the non-inverting terminal of the CMP1 comparator. When V_{CCDIV} drops by SLP_{REF} during the ϕ₁ low period TDET, i.e., V_{CCDIV} is less than or equal to SLP_{REF} in TDET, the output SLP₁ trips indicating that V_{CCIN} is dropping with greater than SLP_{REF}/TDET rate. The Φ₂ phase, C_{B}, and comparator CMP2 are used for continuous detection of V_{CCIN}, even when the ϕ1 phase is in a sampling state.

To make sure throttling is not applied on a true application load transient current, a level comparator CMP0 decides when the slope of V_{CCIN} should be detected. The SLP₁, SLP₂, and SLP_{DET} outputs are processed by a digital logic circuit, and a slope trigger signal SLP_{TRIG} is generated for core throttling. Signal SLP_{TRIG} is high when SLP_{DET} is high and either SLP₁ or SLP₂ are high. The slope rate is adjusted by programming SLP_{REF} voltage, duty cycle, or frequency of ϕ1 and ϕ2.

The slope can be, for example, a value in the range of 100-500 mV/us.

The comparators output the SLP1 and SLP2 signals. SLP_{DET} is triggered when the V_{CCIN} voltage crosses a certain threshold, such as in the range of 1.65-1.75V when V_{CCIN} is in the range of 1.8V. In many implementations, the duration triggering the SLP_{TRIG} signal exceeds two clock pulses (or, equivalently, a predetermined period of time).

When input voltage V_{CCIN} drops with a negative slope greater than a reference slope rate (SR), slope comparators CMP1 and CMP2 trip outputs SLP1 and SLP2. When V_{CCIN} drops below V_{REF,SLP}, SLP_{DET} goes high to indicate to the digital logic to monitor SLP₁ and SLP₂. The digital logic 495 triggers SLP_{TRIG} when SLP₁ is high after SLP_{DET} is high. The reference slope rate SR programming can be performed, where SLP_{REF} sets the numerator voltage drop and ϕ_{1,2} off time, and TDET sets the denominator detection window.

di/dt Detection Using Slope Detector

An on-die di/dt detection scheme is proposed using a slope detector circuit that triggers an error for any specification violation. The di/dt is defined as the rate at which the processor demands current. Some implementations use the slope detector illustrated in FIG. 4.

Currently, di/dt can be estimated with a resistor in a signal path. A system can then determine a current through the resistor and process the current. By processing the current, the system can estimate the voltage at the input of the resistor. Such estimation can consume a substantial amount of time, as well as some power.

A limited number of tests are conducted with fewer workloads or applications to validate for any di/dt violations. Pre-silicon di/dt projections are used for motherboard design and platform design guide spec. The di/dt is estimated using software tools that use multiple parameters such as the fabrication process, switching frequency, the total number of gates in cores, supply voltage, and others.

Specification violations related to large input di/dt cause the MBVR to shut down due to overcurrent protection. These large di/dt violations occur due to heavy or newer application workloads that are not validated. When the MBVR shuts down, it can be unclear whether the issue is with the large di/dt of the processor or if the MBVR is unable to provide the current demand. Currently, there is no method that exists to collect production high volume measurement data on the di/dt ramp.

The proposed di/dt detection scheme can help identify a specification failure due to new workloads or other parameters in the system.

The di/dt detection and telemetry can help identify the root cause of a processor shutdown due to a high current demand, reducing debug time significantly. For example, a customer issue observed in a data center due to a MBVR shutdown bringing their servers down is critical and takes multiple weeks of debugging.

Customers are at higher risk if post-silicon di/dt operation is worse than pre-silicon di/dt projection. This operation increases the product cycle time, cost, and area. Further, existing methods do not identify if newer application workloads on a high-volume processor in the field have caused a large di/dt.

Select implementations of the slope detector can compute the di/dt on the processor input voltage at die-level and take action such as flagging a register (or triggering an error) when the measured di/dt is greater than a reference di/dt.

The supply voltage droop is detected by sensing its rate of fall using a slope-detector circuit.

The current load step response is measured coarsely using the slope detector circuit where the rate of change of V_{CCIN} can be continuously sampled and processed in a digital domain. The two phases of the slope detector circuit can generate pulses SLP₁ and SLP₂ with a duty cycle proportional to the falling rate.

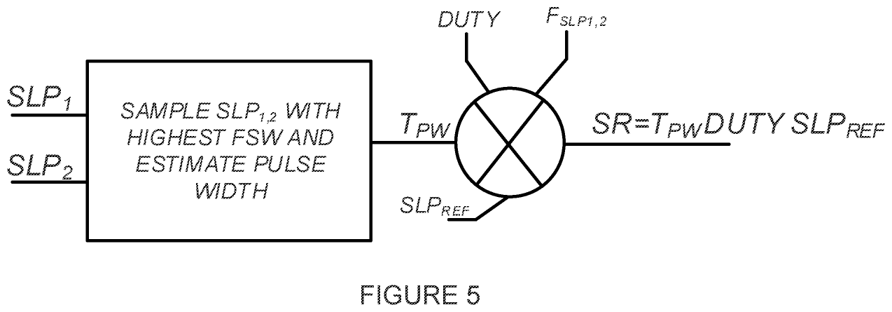

FIG. 5 illustrates a load transient detector architecture, according to an implementation of the present disclosure. The pulse width of SLP_{1,2} is estimated with a high-frequency sampling clock, and the slew rate is calculated using T_{PW}×DUTY×SLP_{REF}, where T_{PW} is the pulse width, DUTY is the duty-cycle selection (Register) used by the slope detector sample-and-hold circuit, and SLP_{REF} is the voltage droop value selected (Register) by the detection window. The calculated slew rate is stored in a register SR_MEASURED. If SR_MEASURED is greater than the reference di/dt set by a SR TARGET register, a SR_FAULT register is set to 1. For controlled diagnostics, when a register SR_EN is enabled, the slew rate is continuously calculated and updated with the highest or average slew rate in the SR_MEASURED register. These registers updates are stopped when a SR_CLR register is set to high. A SR_RES register is used to adjust the resolution, and a SR_COUNTER register is used to count the number of times an SR_FAULT occurred. In many implementations, the calculated slew rate with units Volts/seconds is further divided with load line resistance to obtain di/dt with units Amperes/second.

The di/dt detector can monitor for any platform design specification violation, check if new future workloads can be supported by a processor, and increase current IccIN.Max for future processor stock keeping units (SKUs) without violating input supply specifications.

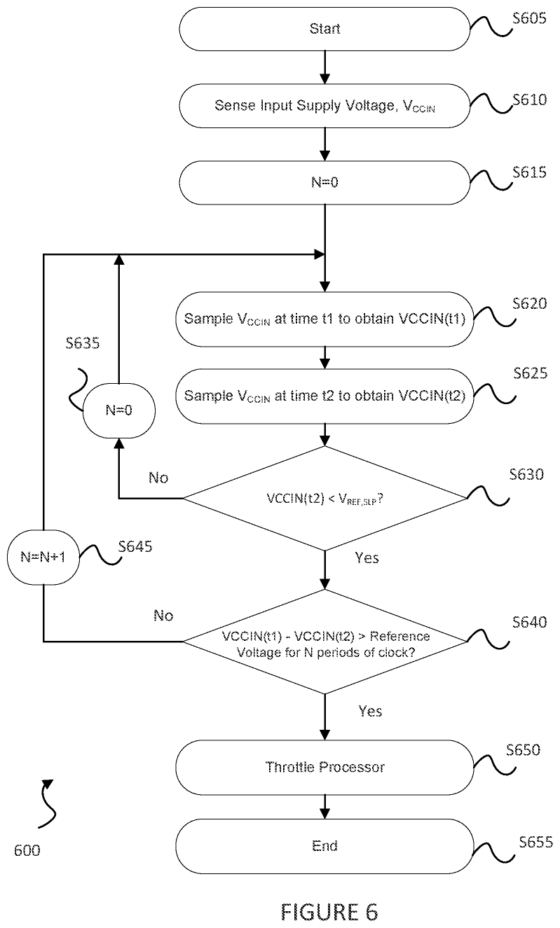

FIG. 6 illustrates an algorithm 600 for throttling a processor according to an implementation of the present disclosure.

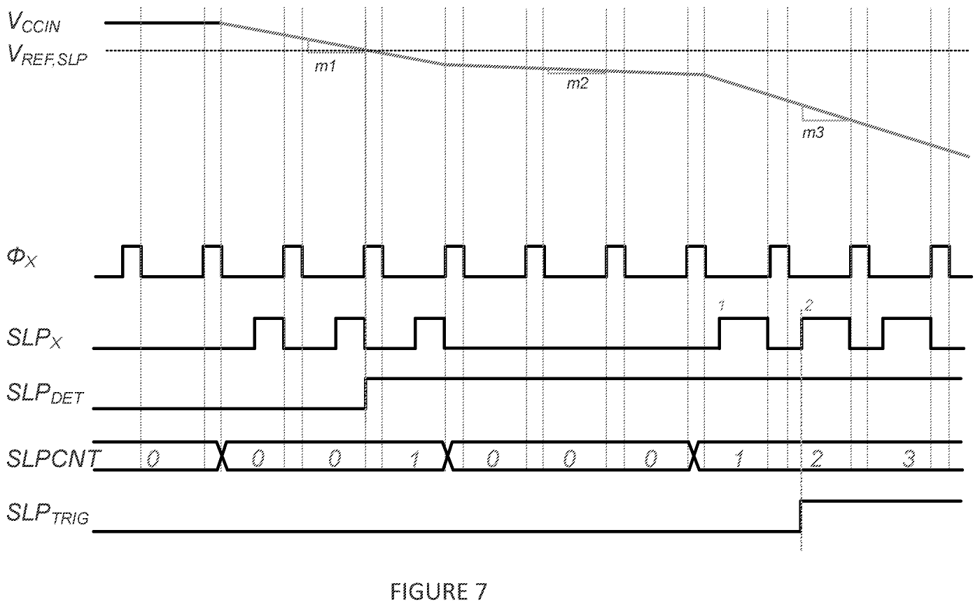

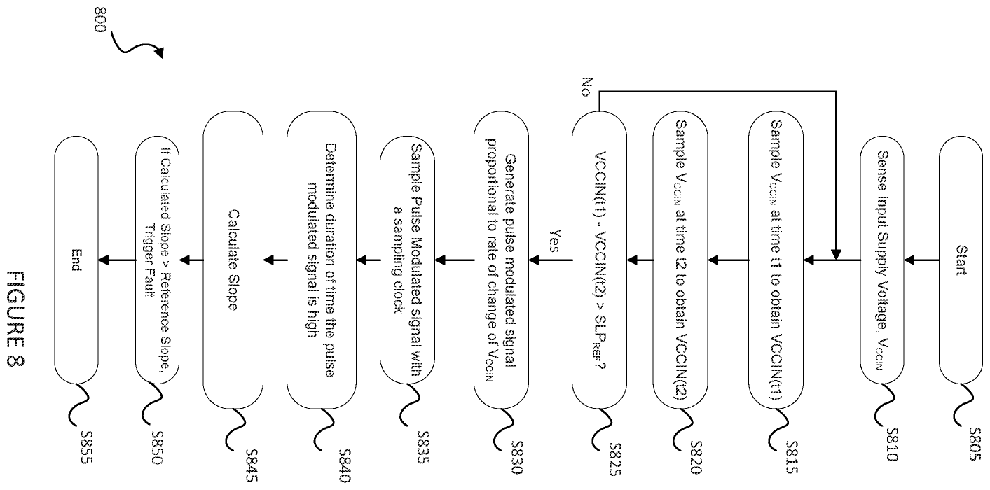

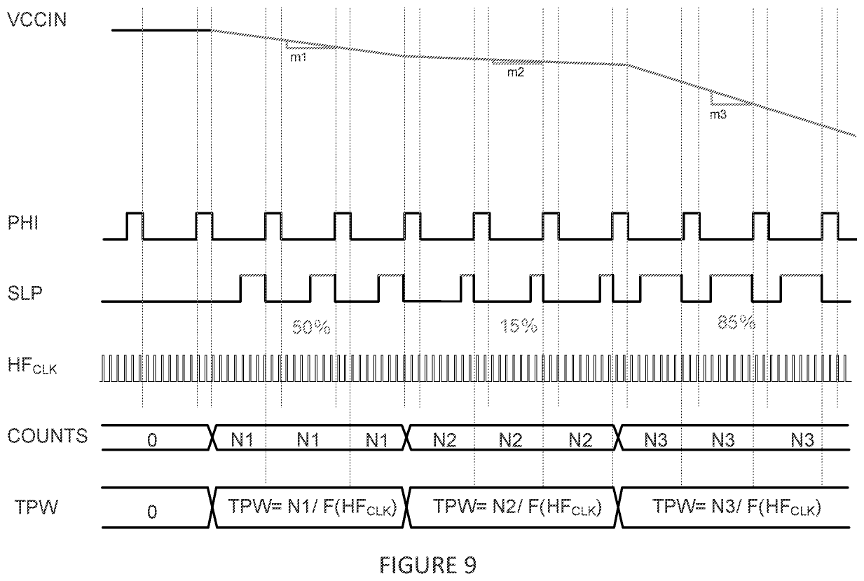

FIG. 7 illustrates an exemplary signal chart during execution of FIG. 6. In particular, FIG. 7 shows a decrease in the input voltage V_{CCIN} over time. The input voltage V_{CCIN} shows four time periods defined by slopes: a first period in which the V_{CCIN} has a slope of m0 equal to 0, a second period in which the input voltage V_{CCIN} has decreased at a first slope m1, a third period in which the input voltage V_{CCIN} decreases at a second slope m2 less than m1, and a fourth period in which the input voltage V_{CCIN} decreases at a third slope m3 greater than m1 and m2.

Returning to FIG. 6, the algorithm 600 begins at S605 and advances to S610.

In S610, a circuit (e.g., voltage divider 410) senses the input supply voltage, according to the present disclosure. In some implementations, this circuit is or includes a voltage divider 410 including one or more resistors (e.g., R_{T} and R_{B}). Select implementations of the voltage divider can include a capacitor and/or inductor. Thus, various implementations of the voltage divider can also perform filtering with the resistor(s), capacitor(s), and/or inductor(s). The voltage divider can produce a divided input voltage V_{CCDIV}. The algorithm 600 then advances to S615.

In S615, the digital logic 495 sets a value N equal to 0. The digital logic 495 can use the value N to represent a number of periods of a clock (e.g., Φ₁). The algorithm 600 then advances to S620.

In S620, the first sample-and-hold circuit 430 samples a voltage (e.g., V_{CCDIV}) based on the input voltage at time t1 to obtain VCCIN(t1). In implementations lacking voltage divider 410, the sampled voltage can be a passthrough supply voltage (e.g., V_{CCIN}). In implementations including voltage divider 410, the sampled voltage can be the divided input voltage. Thus, skilled artisans will recognize that VCCIN(t1) can refer to V_{CCIN} or V_{CCDIV}, depending on the presence of the voltage divider. This sampling occurs when the switch Φ1 closes at clock Φ1=1. In a specific implementation, the clock Φ1 has a programmable duty cycle, such as 10%. The algorithm 600 then advances to S625.

In S625, the sampled voltage is sampled again at time t2 to obtain VCCIN(t2). In many implementations, this sampling is performed by the first sample-and-hold circuit 430. In other implementations, the second sample-and-hold circuit 460 can be suitably modified to perform the sampling.

As with the sampling at S620, the sampling can be performed on a passthrough supply voltage V_{CCIN} or a divided supply voltage V_{CCDIV}.

In many implementations, the sampling of S625 is performed when the switch Φ2 closes when anti phase clock Φ1=0. For example, the sampling can be performed during 90% of the period of clock Φ1. The algorithm 600 then advances to S630.

The input voltage can experience acceptable transient fluctuations. To avoid false positives, the digital logic can trigger on two conditions.

The first condition is the input voltage decreases below a particular voltage. This condition indicates the cause of the decrease is likely due to processor demand, rather than a transient current, for example.

The second condition is the decrease in the input voltage over time (e.g., the slope of its decrease) exceeds a predetermined threshold. This condition indicates the input voltage has a substantial, sustained decrease.

For example, as shown in FIG. 7, in the second period, the respective slope m1 is fairly negative. Further, in the fourth period, the respective slope m3 is substantially negative. Accordingly, in the illustrated example, the signal SLP triggers based on the clock ϕ_{X}.

Further, in the third period, the slope m2 is only slightly negative. So, VCCIN(t1)-VCCIN(t2) is small during measurements conducted during the third period. Accordingly, in the illustrated example, the signal SLP does not trigger.

In S630, the comparator 490 can determine whether VCCIN(t2) is less than a first reference voltage (V_{REF,SLP}), according to the first condition. If the comparator 490 determines that VCCIN(t2) is not less than the first reference voltage (V_{REF,SLP}), then the algorithm 600 advances to S635.

In S635, the digital logic 495 resets N to 0, and the algorithm 600 returns to S620.

Returning to S630, if the comparator 490 determines that VCCIN(t2) is less than the first reference voltage (V_{REF,SLP}), then the algorithm 600 advances to S640.

In S640, the digital logic 495 determines the second condition. Specifically, the digital logic 495 can determine whether VCCIN(t1)-VCCIN(t2) is greater than a second reference voltage SLP_{REF} for N periods of the clock.

If the digital logic 495 determines VCCIN(t1)-VCCIN(t2) is not greater than the second reference voltage for N periods of the clock, then the algorithm 600 advances to S645.

In S645, the digital logic 495 can increment N. The algorithm 600 then returns to S620.

Returning to S640, if the digital logic 495 determines that VCCIN(t1)-VCCIN(t2) is greater than the second reference voltage for N periods of the clock, then the algorithm 600 advances to S650.

In S650, the digital logic 495 produces a signal (SLP_{TRIG}) received by the processor. The processor throttles its frequency upon receiving the signal. The algorithm 600 then advances to S655 and concludes.

Various implementations alternatively or additionally can make a corresponding determination in which the difference between VCCIN(t1) and VCCIN(t2) is divided by the period of a clock and are compared to a reference slope for a predetermined number M of clock periods. This predetermined number M can be N or some other number.

In many implementations, the numbers M, N are natural numbers greater than one. This heightened threshold can indicate whether the slope of the decrease in the input voltage is sustained over a duration exceeding a period of clock Φ₁.

In the example of FIG. 6, the circuit evaluated a first condition at S630 and a second condition at S640. Particular implementations according to the present disclosure can omit either of these conditions or swap their order.

FIG. 8 illustrates an algorithm 800 for performing a di/dt detection according to an implementation of the present disclosure. The algorithm 800 begins at S805 and advances to S810.

In S810, a supply voltage (e.g., V_{CCIN}) can be sensed by the voltage divider circuit 410. Thus, various implementations of the voltage divider 410 can also perform filtering with the resistor(s), capacitor(s), and/or inductor(s). The voltage divider can produce an input voltage V_{CCDIV}. The algorithm 800 then advances to S815.

In S815, the first sample-and-hold circuit 430 samples a voltage based on the input voltage at a first time t1 to obtain a first voltage value VCCIN(t1). This sampling can be based on a signal received from a first clock having a first frequency. The algorithm 800 then advances to S820.

In S820, the input voltage is sampled at a second time t2 to obtain a second voltage value VCCIN(t2). In many implementations, this sampling is performed by the first sample-and-hold circuit 430. In other implementations, the second sample-and-hold circuit 460 can be suitably modified to perform the sampling.

As with the sampling at S815, the sampling can be performed on a passthrough supply voltage V_{CCIN} or a divided supply voltage V_{CCDIV}.

In many implementations, the sampling of S820 is performed when the switch Φ2 closes when clock Φ1=0. For example, the sampling can be performed during 90% of the period of clock Φ1. The algorithm 800 then advances to S825.

In S825, the digital logic 495 determines whether the difference between the first voltage value and the second voltage value is greater than a predetermined threshold voltage (SLP_{REF}).

If the difference between the first voltage value and the second voltage value is not greater than the predetermined threshold voltage, then the algorithm 800 returns to S815.

If the difference between the first voltage value and the second voltage value is greater than the predetermined threshold voltage, the algorithm 800 then advances to S830.

In S830, the sample-and-hold circuits 430, 460 generate a pulse modulated signal (SLP₁ and/or SLP₂) that is proportional to the rate of change of V_{CCIN} between times t1 and t2. Although S830 is shown as occurring after S825, it is expressly contemplated that S830 also can be performed before or in parallel with S825. The algorithm 800 then advances to S835.

In S835, a sampling clock (not pictured) samples the pulse modulated signal. The sampling clock has a second frequency that can be higher than the first frequency of clock Φ1, in various implementations. The algorithm 800 then advances to S840.

In S840, the digital logic 495 determines a duration of time (TPW) that the pulse modulated signal is high. This determination can be performed based on the sample generated with the sampling clock in S835. The algorithm 800 then advances to S845.

In S845, the digital logic 495 calculates a slope indicating how quickly the slope of the input voltage is changing. In many implementations, this slope can be equal to the voltage SLP_{REF} divided by the duration TPW determined in S840. The algorithm 800 then advances to S850.

In S850, the digital logic 495 determines whether the slope calculated in S845 is greater than a predetermined reference slope. If the slope calculated in S845 is greater than the predetermined reference slope, then the digital logic 495 triggers a fault signal. One example of this fault is sending a signal to a logging device. In some implementations, triggering the fault also includes sending telemetry data, such as a processor dump. The algorithm 800 then advances to S855.

In S855, the algorithm 800 concludes.

Particular implementations can perform telemetry (e.g., sensing) to perform remote debugging. For example, a customer's processor might shut down, and it is unclear whether the problem lies in the chip itself or the customer's code. Thus, additionally or alternatively to throttling the processor and/or triggering a fault, the digital logic can transmit telemetry data. The telemetry data can include, for example, the change in voltage, the change in current, the time difference, and/or the slope.

Implementations can improve the processor performance. Select implementations can reduce the cost of the platform by reducing the amount of capacitance that would have been used to achieve early detection.

This disclosure describes Boolean functions like “greater than” and “less than.” This description is non-limiting in that a skilled artisan would understand “greater than” to also describe options of “greater than or equal to,” “not less than,” or “not less than or equal to.” A skilled artisan would correspondingly understand the phrase “less than.”

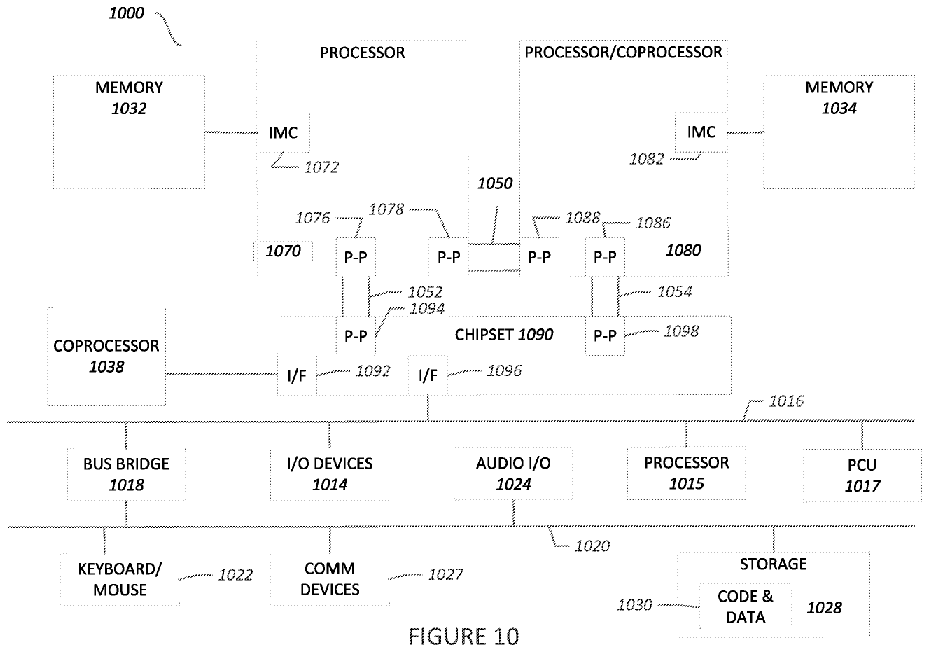

FIG. 10 illustrates an example computing system, according to an implementation of the present disclosure. Multiprocessor system 1000 is an interfaced system and includes a plurality of processors including a first processor 1070 and a second processor 1080 coupled via an interface 1050 such as a point-to-point (P-P) interconnect, a fabric, and/or bus. In some examples, the first processor 1070 and the second processor 1080 are homogeneous. In some examples, first processor 1070 and the second processor 1080 are heterogenous. Though the example system 1000 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 1070 and 1080 are shown including integrated memory controller (IMC) circuitry 1072 and 1082, respectively. Processor 1070 also includes interface circuits 1076 and 1078, along with core sets. Similarly, second processor 1080 includes interface circuits 1086 and 1088, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 1070, 1080 may exchange information via the interface 1050 using interface circuits 1078, 1088. IMCs 1072 and 1082 couple the processors 1070, 1080 to respective memories, namely a memory 1032 and a memory 1034, which may be portions of main memory locally attached to the respective processors.

Processors 1070, 1080 may each exchange information with a network interface (NW I/F) 1090 via individual interfaces 1052, 1054 using interface circuits 1076, 1094, 1086, 1098. The network interface 1090 (e.g., one or more of an interconnect, bus, and/or fabric, and in some examples is a chipset) may optionally exchange information with a coprocessor 1038 via an interface circuit 1092. In some examples, the coprocessor 1038 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 1070, 1080 or outside of both processors, yet connected with the processors via an interface such as P-P interconnect, such that either or both processors' local cache information may be stored in the shared cache if a processor is placed into a low power mode.

Network interface 1090 may be coupled to a first interface 1016 via interface circuit 1096. In some examples, first interface 1016 may be an interface such as a Peripheral Component Interconnect (PCI) interconnect, a PCI Express interconnect, or another I/O interconnect. In some examples, first interface 1016 is coupled to a power control unit (PCU) 1017, which may include circuitry, software, and/or firmware to perform power management operations with regard to the processors 1070, 1080 and/or co-processor 1038. PCU 1017 provides control information to one or more voltage regulators (not shown) to cause the voltage regulator(s) to generate the appropriate regulated voltage(s). PCU 1017 also provides control information to control the operating voltage generated. In various examples, PCU 1017 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 1017 is illustrated as being present as logic separate from the processor 1070 and/or processor 1080. In other cases, PCU 1017 may execute on a given one or more of cores (not shown) of processor 1070 or 1080. In some cases, PCU 1017 may be implemented as a microcontroller (dedicated or general-purpose) or other control logic configured to execute its own dedicated power management code, sometimes referred to as P-code. In yet other examples, power management operations to be performed by PCU 1017 may be implemented externally to a processor, such as by way of a separate power management integrated circuit (PMIC) or another component external to the processor. In yet other examples, power management operations to be performed by PCU 1017 may be implemented within Basic Input Output System (BIOS) or other system software. Along these lines, power management may be performed in concert with other power control units implemented autonomously or semi-autonomously, e.g., as controllers or executing software in cores, clusters, intellectual property (IP) blocks and/or in other parts of the overall system.

Various input/output (I/O) devices 1014 may be coupled to first interface 1016, along with a bus bridge 1018 which couples first interface 1016 to a second interface 1020. In some examples, one or more additional processor(s) 1015, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 1016. In some examples, second interface 1020 may be a low pin count (LPC) interface. Various devices may be coupled to second interface 1020 including, for example, a keyboard and/or mouse 1022, communication devices 1027 and storage circuitry 1028. Storage circuitry 1028 may be one or more non-transitory machine-readable storage media as described below, such as a disk drive or other mass storage device which may include instructions/code and data 1030 in some examples. Further, an audio I/O 1024 may be coupled to second interface 1020. Note that other architectures than the point-to-point architecture described above are possible. For example, instead of the point-to-point architecture, a system such as multiprocessor system woo may implement a multi-drop interface or other such architecture.

Example Core Architectures, Processors, and Computer Architectures.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality.

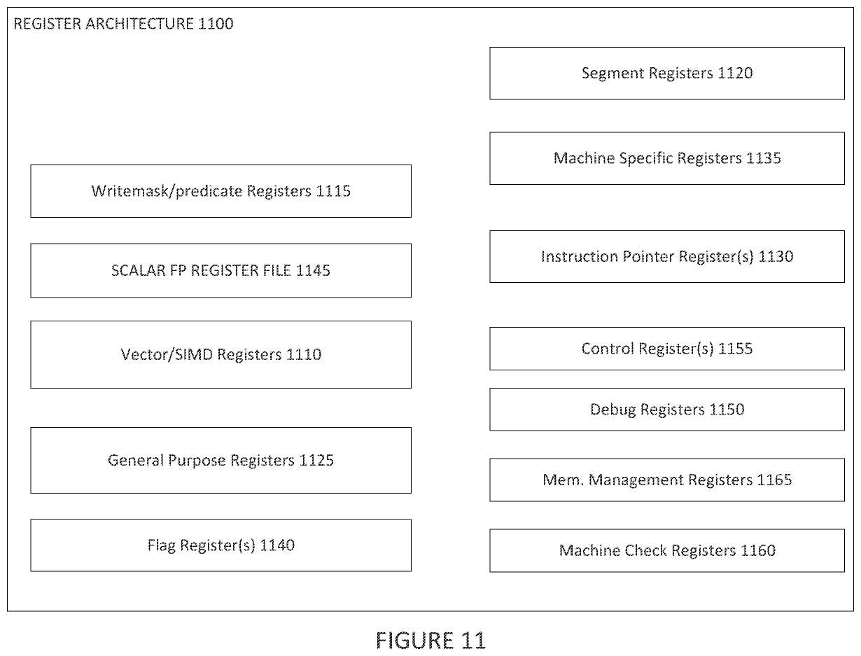

FIG. 11 is a block diagram of a register architecture 1100 according to some examples. As illustrated, the register architecture 1100 includes vector/SIMD (single instruction, multiple data) registers 1110 that vary from 128-bit to 1,024 bits width. In some examples, the vector/SIMD registers 1110 are physically 512-bits and, depending upon the mapping, only some of the lower bits are used. For example, in some examples, the vector/SIMD registers 1110 are ZMM registers which are 512 bits: the lower 256 bits are used for YMM registers and the lower 128 bits are used for XMM registers. As such, there is an overlay of registers. In some examples, a vector length field selects between a maximum length and one or more other shorter lengths, where each such shorter length is half the length of the preceding length. Scalar operations are operations performed on the lowest order data element position in a ZMM/YMM/XMM register; the higher order data element positions are either left the same as they were prior to the instruction or zeroed depending on the example.

In some examples, the register architecture 1100 includes writemask/predicate registers 1115. For example, in some examples, there are 8 writemask/predicate registers (sometimes called k0 through k7) that are each 16-bit, 32-bit, 64-bit, or 128-bit in size. Writemask/predicate registers 1115 may allow for merging (e.g., allowing any set of elements in the destination to be protected from updates during the execution of any operation) and/or zeroing (e.g., zeroing vector masks allow any set of elements in the destination to be zeroed during the execution of any operation). In some examples, each data element position in a given writemask/predicate register 1115 corresponds to a data element position of the destination. In other examples, the writemask/predicate registers 1115 are scalable and consists of a set number of enable bits for a given vector element (e.g., 8 enable bits per 64-bit vector element).

The register architecture 1100 includes a plurality of general-purpose registers 1125. These registers may be 16-bit, 32-bit, 64-bit, etc. and can be used for scalar operations. In some examples, these registers are referenced by the names RAX, RBX, RCX, RDX, RBP, RSI, RDI, RSP, and R8 through R15.

In some examples, the register architecture 1100 includes scalar floating-point (FP) register file 1145 which is used for scalar floating-point operations on 32/64/80-bit floating-point data using the x87 instruction set architecture extension or as MMX registers to perform operations on 64-bit packed integer data, as well as to hold operands for some operations performed between the MMX and XMM registers.

One or more flag registers 1140 (e.g., EFLAGS, RFLAGS, etc.) store status and control information for arithmetic, compare, and system operations. For example, the one or more flag registers 1140 may store condition code information such as carry, parity, auxiliary carry, zero, sign, and overflow. In some examples, the one or more flag registers 1140 are called program status and control registers.

Segment registers 1120 contain segment points for use in accessing memory. In some examples, these registers are referenced by the names CS, DS, SS, ES, FS, and GS.

Machine specific registers (MSRs) 1135 control and report on processor performance. Most MSRs 1135 handle system-related functions and are not accessible to an application program. Machine check registers 1160 consist of control, status, and error reporting MSRs that are used to detect and report on hardware errors.

One or more instruction pointer register(s) 1130 store an instruction pointer value. Control register(s) 1155 (e.g., CR0-CR4) determine the operating mode of a processor (e.g., processor 1070, 1080, 1038, and/or 1015) and the characteristics of a currently executing task. Debug registers 1150 control and allow for the monitoring of a processor or core's debugging operations.

Memory (mem) management registers 1165 specify the locations of data structures used in protected mode memory management. These registers may include a global descriptor table register (GDTR), interrupt descriptor table register (IDTR), task register, and a local descriptor table register (LDTR) register.

Alternative examples may use wider or narrower registers. Additionally, alternative examples may use more, less, or different register files and registers. The register architecture 1100 may, for example, be used in register file/memory or physical register file(s) circuitry.

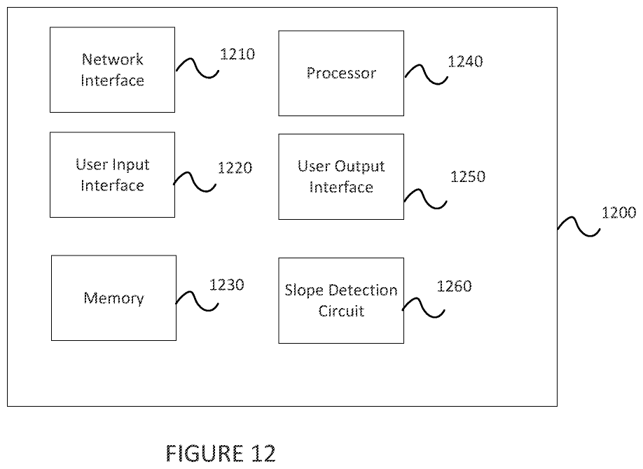

FIG. 12 illustrates a computing device 1200, according to an implementation of the present disclosure. The computing device 1200 can include a network interface 1210, a user input interface 1220, a memory 1230, a processor 1240, a user output interface 1250, and a slope detection circuit 1260.

Although illustrated within a single housing, the computing device 1200 can be distributed across plural housings or sub-systems that cooperate in executing program instructions. In some implementations, the computing device 1200 can include one or more blade server devices, standalone server devices, personal computers, routers, hubs, switches, bridges, firewall devices, intrusion detection devices, mainframe computers, network-attached storage devices, smartphones and other mobile telephones, and other types of computing devices. The system hardware can be configured according to any computer architecture, such as a Symmetric Multi-Processing (SMP) architecture or a Non-Uniform Memory Access (NUMA) architecture.

The network interface 1210 provides one or more communication connections and/or one or more devices that allow for communication between the computing device 1200 and other computing systems (not shown) over a communication network or collection of networks (not shown) or the air. The network interface can communicate using near-field communications (NFC), Wi-Fi™, Bluetooth, Ethernet, facsimile, or any other wired or wireless interface.

The user input interface 1220 receives inputs from a human. The user input interface 1220 can be or include a mouse, a touchpad, a keyboard, a touchscreen, a trackball, a camera, a microphone, a joystick, a game controller, a scanner, a stylus, or any other input device.

The memory 1230, also termed a “storage,” can include or be one or more computer-readable storage media readable by the processor 1240 and that store software. The memory 1230 can be implemented as one storage device and can also be implemented across multiple co-located or distributed storage devices or sub-systems. The memory 1230 can include additional elements, such as a controller, that communicate with the processor 1240. The memory 1230 can also include storage devices and/or sub-systems on which data and/or instructions are stored. The computing device 1200 can access one or more storage resources to access information to carry out any of the clock compensation processes indicated in this disclosure.

The memory 1230 can be or include a read-only memory (ROM), a programmable ROM (PROM), an erasable PROM (EPROM), an electrically erasable PROM (EEPROM), a random-access memory (RAM), a dynamic RAM (DRAM), a static RAM (SRAM), a hard drive, a cache memory, a flash memory, a removable disk, or a tape reel. The memory 1230 can be or include resistive RAM (RRAM) or a magneto-resistive RAM (MRAM).

Software stored in the memory 1230 can include routines for at least partially performing at least one of the clock compensation processes and can be implemented in program instructions. Further, the software, when executed by the computing device 1200 in general or the processor 1240 specifically, can direct, among other functions, the computing device 1200 or the processor 1240 to perform the slope detection as described herein.

The processor 1240 can be or include one or more hardware processors and/or other circuitry that retrieve and execute software from the memory 1230. The processor 1240 can be implemented within one processing device, chip, or package and can also be distributed across multiple processing devices, chips, packages, or sub-systems that cooperate in executing program instructions.

In some implementations, the processor 1240 is or includes a Graphics Processing Unit (GPU). The GPU can benefit the visual/image processing in the computing device 1200. The GPU, or any second-order processing element independent from the processor 1240 dedicated to processing imagery and other perception data in real or near real-time, can provide a processing benefit for video processing or other applications (e.g., cryptocurrency).

The processor 1240 can have any register size, such as a 32-bit register or a 64-bit register, among others. The processor 1240 can include multiple cores. Implementations of the processor 1240 are not limited to any particular number of threads. The processor 1240 can be fabricated by any process technology, such as 14 nm process technology.

The user output interface 1250 outputs information to a human user. The user output interface 1250 can be or include a display (e.g., a screen), a touchscreen, one or more speakers, a printer, or a haptic feedback unit. In some implementations, the user output interface 1250 displays quick response (QR) codes for communication with other devices.

The slope detection circuit 1260 can be or include slope detector 400 or other implementation according to the present disclosure and/or appended claims.

In implementations where the system 1200 includes multiple computing devices, a server of the system or, in a serverless implementation, a peer can use one or more communications networks that facilitate communication among the computing devices. For example, the one or more communications networks can include or be a local area network (LAN), wide area network (WAN), or Metropolitan Area Network (MAN) that facilitate communication among the computing devices. One or more direct communication links can be included between the computing devices. In addition, in some cases, the computing devices can be installed at geographically distributed locations. In other cases, the multiple computing devices can be installed at one geographic location, such as a server farm or an office.

As used herein, the terms “storage media,” “computer-readable storage media,” or “computer-readable storage medium” can refer to non-transitory storage media, such as a hard drive, a memory chip, and cache memory, and to transitory storage media, such as carrier waves or propagating signals.

Aspects of the system for slope detection can be implemented in various manners (e.g., as a method, a system, a computer program product, or one or more computer-readable storage media). Accordingly, aspects of the present disclosure can take the form of a hardware implementation, a software implementation (including firmware, resident software, or micro-code) or an implementation combining software and hardware aspects that can generally be referred to herein as a “circuit,” “module” or “system.” Functions described in this disclosure can be implemented as an algorithm executed by one or more hardware processing units, e.g., one or more microprocessors of one or more computers. In various embodiments, different operations and portions of the operations of the methods described can be performed by different processing units. Furthermore, aspects of the present disclosure can take the form of a computer program product embodied in one or more computer-readable media having computer-readable program code embodied, e.g., encoded or stored, thereon. In various implementations, such a computer program can, for example, be downloaded to (or updated on) existing devices and systems or be stored upon manufacturing of these devices and systems.

In the description, reference is made to the drawings where like reference numerals can indicate identical or functionally similar elements. Elements illustrated in the drawings are not necessarily drawn to scale. Additionally, certain implementations can include more or fewer elements than illustrated in a drawing and/or a subset of the elements illustrated in a drawing. Further, some implementations can incorporate a suitable combination of features from two or more drawings.

The components, arrangements, and/or features of the disclosure are described in connection with various implementations and are merely examples to simplify the present disclosure and are not intended to be limiting. In the development of actual implementations, implementation-specific decisions can be made to achieve a developer's specific goals, including compliance with system, business, and/or legal constraints, that can vary from one implementation to another. Additionally, while such a development effort might be complex and time-consuming, it would be a routine undertaking for those of ordinary skill in the art having the benefit of this disclosure.

The attached drawings depict spatial relationships between various components and to the spatial orientation of various aspects of components. The devices, components, members, and apparatuses can be positioned in any orientation. Thus, the use of terms such as “above”, “below”, “upper”, “lower”, “top”, “bottom”, or other similar terms to describe a spatial relationship between various components or to describe the spatial orientation of aspects of such components describes a relative relationship between the components or a spatial orientation of aspects of such components, respectively, as the components described can be oriented in any direction.

The systems, methods and devices of this disclosure have several innovative aspects, no one of which is solely responsible for the attributes disclosed herein. Some objects or advantages might not be achieved by implementations described herein. Thus, for example, certain implementations can operate in a manner that achieves or optimizes one advantage or group of advantages as taught herein and not other objects or advantages as taught or suggested herein.

In one example implementation, electrical circuits of the drawings can be implemented on a board of an associated electronic device. The board can be a general circuit board that holds components of the internal electronic system of the electronic device and, further, provide connectors for other peripherals. More specifically, the board can provide the electrical connections by which other components of the system can communicate electrically. Any processors (inclusive of digital signal processors, microprocessors, supporting chipsets, etc.) and computer-readable non-transitory memory elements can be coupled to the board based on configurations, processing demands, and computer designs. Other components such as external storage, additional sensors, controllers for audio/video display, and peripheral devices can be attached to the board as plug-in cards, via cables, or integrated into the board itself. In various implementations, the functionalities described herein can be implemented in an emulation form as software or firmware running within one or more configurable (e.g., programmable) elements arranged in a structure that supports these functions. The software or firmware providing the emulation can be provided on one or more non-transitory, computer-readable storage media including instructions to allow one or more processors to carry out those functionalities.

In another example implementation, the electrical circuits of the drawings can be implemented as stand-alone modules (e.g., a device with associated components and circuitry configured to perform a specific application or function) or implemented as plug-in modules into application-specific hardware of electronic devices. Implementations of the present disclosure can be readily included in a system-on-chip (SOC) package. An SOC represents an integrated circuit (IC) that integrates components of a computer or other electronic system into one chip. The SOC can contain digital, analog, mixed-signal, and radio frequency functions. Other implementations can include a multi-chip-module (MCM) with a plurality of separate ICs located within one electronic package and that interact through the electronic package. In various other implementations, the processors can be implemented in one or more silicon cores in Application Specific Integrated Circuits (ASICs), Field Programmable Gate Arrays (FPGAs), programmable array logic (PAL), generic array logic (GAL), and other semiconductor chips.

The specifications, dimensions, and relationships outlined herein (e.g., the number of processors, logic operations, delay lines) have been offered for non-limiting purposes of example and teaching. Various modifications and changes can be made to arrangements of such components. The description and drawings are, accordingly, to be regarded in an illustrative sense, not in a restrictive sense.

With the numerous examples provided herein, interaction was described in terms of two, three, or more electrical components for purposes of clarity and example. The system can be consolidated in any manner. Along similar design alternatives, the illustrated components, modules, and elements of the drawings can be combined in various possible configurations within the scope of this disclosure. In certain cases, it might be easier to describe one or more of the functionalities of a given set of flows by referencing a limited number of electrical elements. The electrical circuits of the drawings and their teachings are readily scalable and can accommodate many components, as well as more complicated/sophisticated arrangements and configurations. Accordingly, the examples provided do not limit the scope or inhibit the teachings of the electrical circuits as potentially applied to a myriad of other architectures.

In this disclosure, references to various features (e.g., elements, structures, modules, components, operations, characteristics, etc.) included in “one implementation”, “example implementation”, “an implementation”, “another implementation”, “some implementations”, “various implementations”, “other implementations”, “alternative implementation”, and the like are intended to mean that any such features are included in one or more implementations of the present disclosure and might or might not necessarily be combined in the same implementations. Some operations can be deleted or omitted where appropriate, or these operations can be modified or changed considerably. In addition, the timing of these operations can be altered considerably. The preceding operational flows have been offered for purposes of example and discussion. Implementations described herein provide flexibility in that any suitable arrangements, chronologies, configurations, and timing mechanisms can be provided.

### EXAMPLES

The following examples pertain to further embodiments.

Example 1A1 is an apparatus, comprising: a circuit to generate a clock having a period with a duty cycle less than or equal to 90%; and logic to determine a difference in an input voltage between a first time and a second time, at least in part based on the duty cycle of the clock, and to produce a first signal, at least in part based on the difference in the input voltage and a first predetermined threshold.

In Example 1A2, the subject matter of Example 1A1 can optionally include the feature that the logic further is to determine a first value of the input voltage at a first time, at least in part based on the duty cycle of the clock.

In Example 1A3, the subject matter of Example 1A2 can optionally include the feature that the logic further is to determine a second value of the input voltage at a second time, at least in part based on a remainder of the period of the clock.

In Example 1A4, the subject matter of Example 1A3 can optionally include the feature that the difference is determined, at least in part based on a difference between the second value and the first value.

In Example 1A5, the subject matter of any of Examples 1A1-1A4 can optionally include the feature that the logic further is to produce the first signal, at least in part based on a determination that the magnitude of the difference in the input voltage exceeds the magnitude of the first predetermined threshold for a predetermined number of periods of the clock, and the predetermined number of periods is greater than 1.

In Example 1A6, the subject matter of Example 1A5 can optionally include the feature that the first signal throttles a processor.

In Example 1A7, the subject matter of Example 1A6 can optionally include the processor, wherein the processor receives the input voltage and the first signal.

In Example 1A8, the subject matter of any of Examples 1A1-1A7 can optionally include a level comparator to produce a second signal indicating whether the sampled voltage is less than a reference voltage.

In Example 1A9, the subject matter of any of Examples 1A1-1A8 can optionally include the feature that the logic produces the first signal, at least in part based on the second signal.

In Example 1A10, the subject matter of any of Examples 1A1-1A9 can optionally include a sample-and-hold circuit that samples the input voltage.

In Example 1A11, the subject matter of any of Examples 1A1-1A10 can optionally include a voltage divider that receives a supply voltage and produces the input voltage, wherein the input voltage is at least in part based on the divided voltage.

Example 1M1 is a method implemented by an apparatus, the method comprising: determining a difference in an input voltage between a first time and a second time, at least in part based on a duty cycle of a clock, the duty cycle being less than or equal to 90% of a period of the clock; and producing a first signal, at least in part based on the difference in the input voltage and a first predetermined threshold.

In Example 1M2, the subject matter of Example 1M1 can optionally include determining a first value of the input voltage at a first time, at least in part based on the duty cycle of the clock.

In Example 1M3, the subject matter of Example 1M2 can optionally include determining a second value of the input voltage at a second time, at least in part based on a remainder of the period of the clock.

In Example 1M4, the subject matter of Example 1M3 can optionally include the feature that the difference is determined, at least in part based on a difference between the second value and the first value.

In Example 1M5, the subject matter of any of Examples 1M1-1M4 can optionally include producing the first signal, at least in part based on a determination that the magnitude of the difference in the input voltage exceeds the magnitude of the first predetermined threshold for a predetermined number of periods of the clock, wherein the predetermined number of periods is greater than 1.

In Example 1M6, the subject matter of Example 1M5 can optionally include the feature that the first signal throttles a processor.

In Example 1M7, the subject matter of Example 1M6 can optionally include the feature that the apparatus includes the processor, and the processor receives the input voltage and the first signal.

In Example 1M8, the subject matter of any of Examples 1M1-1M7 can optionally include producing, with a level comparator, a second signal indicating whether the sampled voltage is less than a reference voltage.

In Example 1M9, the subject matter of Example 1M8 can optionally include the feature that the producing the first signal produces the first signal, at least in part based on the second signal.

In Example 1M10, the subject matter of any of Examples 1M1-1M9 can optionally include sampling, with a sample-and-hold circuit, the input voltage.

In Example 1M11, the subject matter of any of Examples 1M1-1M10 can optionally include receiving, with a voltage divider, a supply voltage; and producing, with the voltage divider, the input voltage, wherein the input voltage is at least in part based on the divided voltage.

Example 1C1 is a non-transitory, computer-readable medium encoded with instructions that, when executed by an electronic apparatus, cause the electronic apparatus to perform a method comprising: determining a difference in an input voltage between a first time and a second time, at least in part based on a duty cycle of a clock, the duty cycle being less than or equal to 90% of a period of the clock; and producing a first signal, at least in part based on the difference in the input voltage and a first predetermined threshold.

In Example 1C2, the subject matter of Example Xi can optionally include the feature of the method further comprising: determining a first value of the input voltage at a first time, at least in part based on the duty cycle of the clock.

In Example 1C3, the subject matter of Example 1C2 can optionally include the feature of the method further comprising: determining a second value of the input voltage at a second time, at least in part based on a remainder of the period of the clock.

In Example 1C4, the subject matter of Example 1C3 can optionally include the feature that the difference is determined, at least in part based on a difference between the second value and the first value.

In Example 105, the subject matter of any of Examples 1C1-1C4 can optionally include the feature of the method further comprising: producing the first signal, at least in part based on a determination that the magnitude of the difference in the input voltage exceeds the magnitude of the first predetermined threshold for a predetermined number of periods of the clock, wherein the predetermined number of periods is greater than 1.

In Example 1C6, the subject matter of Example 105 can optionally include the feature that the first signal throttles a processor.

In Example 1C7, the subject matter of Example 1C6 can optionally include the feature that the electronic apparatus includes the processor, and the processor receives the input voltage and the first signal.

In Example 1C8, the subject matter of any of Examples 1C1-1C7 can optionally include the feature of the method further comprising: receiving, from a level comparator, a second signal indicating whether the sampled voltage is less than a reference voltage.

In Example 1C9, the subject matter of Example 1C8 can optionally include the feature that the producing the first signal produces the first signal, at least in part based on the second signal.

In Example 1C10, the subject matter of any of Examples 1C1-1C9 can optionally include the feature of the method further comprising: receiving, from a sample-and-hold circuit, a sample of the input voltage.

In Example 1C11, the subject matter of any of Examples 1C1-1C10 can optionally include the feature that the input voltage is at least in part based on a divided voltage received from a voltage divider.

Example 1F1 is an apparatus, comprising: means for determining a difference in an input voltage between a first time and a second time, at least in part based on a duty cycle of a clock, the duty cycle being less than or equal to 90% of a period of the clock; and means for producing a first signal, at least in part based on the difference in the input voltage and a first predetermined threshold.

In Example 1F2, the subject matter of Example 1F1 can optionally include means for determining a first value of the input voltage at a first time, at least in part based on the duty cycle of the clock.

In Example 1F3, the subject matter of Example 1F2 can optionally include means for determining a second value of the input voltage at a second time, at least in part based on a remainder of the period of the clock.

In Example 1F4, the subject matter of Example 1F3 can optionally include the feature that the difference is determined, at least in part based on a difference between the second value and the first value.

In Example 1F5, the subject matter of any of Examples 1F1-1F4 can optionally include the feature that the means for producing produces the first signal, at least in part based on a determination that the magnitude of the difference in the input voltage exceeds the magnitude of the first predetermined threshold for a predetermined number of periods of the clock, and the predetermined number of periods is greater than 1.

In Example 1F6, the subject matter of Example 1F5 can optionally include the feature that the first signal throttles a processor.

In Example 1F7, the subject matter of Example 1F6 can optionally include the feature that the apparatus includes the processor, and the processor receives the input voltage and the first signal.

In Example 1F8, the subject matter of any of Examples 1F1-1F7 can optionally include means for producing a second signal indicating whether the sampled voltage is less than a reference voltage.

In Example 1F9, the subject matter of Example 1F8 can optionally include the feature that means for producing produces the first signal, at least in part based on the second signal.

In Example 1F10, the subject matter of any of Examples 1F1-1F9 can optionally include means for sampling the input voltage.

In Example 1F11, the subject matter of Example 08 can optionally include means for receiving a supply voltage and for producing the input voltage, wherein the input voltage is at least in part based on the divided voltage.

Example 1S1 is a system, comprising: a circuit to generate a clock having a period with a duty cycle less than or equal to 90%; logic to determine a difference in an input voltage between a first time and a second time, at least in part based on the duty cycle of the clock, and to produce a first signal, at least in part based on the difference in the input voltage and a first predetermined threshold; and a processor that receives the first signal.

In Example 1S2, the subject matter of Example 1S1 can optionally include the feature that the logic further is to determine a first value of the input voltage at a first time, at least in part based on the duty cycle of the clock.

In Example 1S3, the subject matter of Example 1S2 can optionally include the feature that the logic further is to determine a second value of the input voltage at a second time, at least in part based on a remainder of the period of the clock.

In Example 1S4, the subject matter of Example 1S3 can optionally include the feature that the difference is determined, at least in part based on a difference between the second value and the first value.

In Example 1S5, the subject matter of any of Examples 1S1-1S4 can optionally include the feature that the logic further is to produce the first signal, at least in part based on a determination that the magnitude of the difference in the input voltage exceeds the magnitude of the first predetermined threshold for a predetermined number of periods of the clock, and the predetermined number of periods is greater than 1.

In Example 1S6, the subject matter of Example 1S5 can optionally include the feature that the first signal throttles the processor.

In Example 1S7, the subject matter of Example 1S6 can optionally include the feature that the processor receives the input voltage.

In Example 1S8, the subject matter of any of Examples 1S1-187 can optionally include a level comparator to produce a second signal indicating whether the sampled voltage is less than a reference voltage.

In Example 1S9, the subject matter of any of Examples 1S1-1S8 can optionally include the feature that the logic produces the first signal, at least in part based on the second signal.

In Example 1S10, the subject matter of any of Examples 1S1-1S9 can optionally include a sample-and-hold circuit that samples the input voltage.

In Example 1S11, the subject matter of any of Examples 1S1-1S10 can optionally include a voltage divider that receives a supply voltage and produces the input voltage, wherein the input voltage is at least in part based on the divided voltage.

Example 2A1 is an apparatus, comprising: a first circuit to generate a first clock having a first frequency; and logic to determine a change in an input voltage over time, at least in part based on the first frequency, and to produce a first signal, at least in part based on the magnitude of the change in the input voltage over time and a predetermined threshold.

In Example 2A2, the subject matter of Example 2A1 can optionally include the feature that the logic further is to generate a second signal indicating a rate of change of the input voltage over time, and the first signal is at least in part based on the second signal.

In Example 2A3, the subject matter of Example 2A2 can optionally include the feature that the second signal is a pulse-width signal proportional to the rate of change of the input voltage over time.

In Example 2A4, the subject matter of Example 2A3 can optionally include a second circuit to generate a second clock having a second frequency higher than the first frequency, wherein the logic further is to sample the pulse-width signal with the second clock.

In Example 2A5, the subject matter of Example 2A4 can optionally include the feature that the logic further is to compute a duration that the pulse-width signal is asserted, at least in part based on the second frequency.

In Example 2A6, the subject matter of any of Examples 2A3-2A5 can optionally include a sample-and-hold circuit to produce the pulse-width signal, at least in part based on the input voltage.

In Example 2A7, the subject matter of any of Examples 2A1-2A6 can optionally include the feature that the logic further is to divide a reference voltage by the duration to produce the predetermined threshold.

In Example 2A8, the subject matter of any of Examples 2A1-2A7 can optionally include the feature that the logic further is to sample the input voltage to obtain a first value of the input voltage at a first time and a second value of the input voltage at a second time, and the change in the input voltage is determined at least in part based on the first value and the second value.

In Example 2A9, the subject matter of Example 2A8 can optionally include the feature that the logic further is to perform a determination that a magnitude of a difference between the first value and the second value exceeds a magnitude of a predetermined threshold, and the first signal is produced, at least in part based on the determination.

In Example 2A10, the subject matter of any of Examples 2A1-2A9 can optionally include a processor that receives the input voltage.

In Example 2A11, the subject matter of any of Examples 2A1-2A10 can optionally include a voltage divider that receives a supply voltage and produces the input voltage.

Example 2M1 is a method, comprising: determining a change in an input voltage over time, at least in part based on a first frequency of a first clock; and producing a first signal, at least in part based on the magnitude of the change in the input voltage over time and a predetermined threshold.

In Example 2M2, the subject matter of Example 2M1 can optionally include generating a second signal indicating a rate of change of the input voltage over time, wherein the first signal is at least in part based on the second signal.

In Example 2M3, the subject matter of Example 2M2 can optionally include the feature that the second signal is a pulse-width signal proportional to the rate of change of the input voltage over time.

In Example 2M4, the subject matter of Example 2M3 can optionally include sampling the pulse-width signal with a second clock having a second frequency higher than the first frequency.

In Example 2M5, the subject matter of Example 2M4 can optionally include computing a duration that the pulse-width signal is asserted, at least in part based on the second frequency.

In Example 2M6, the subject matter of any of Examples 2M3-2M5 can optionally include producing, with a sample-and-hold circuit, the pulse-width signal, at least in part based on the input voltage.

In Example 2M7, the subject matter of any of Examples 2M1-2M6 can optionally include dividing a reference voltage by the duration to produce the predetermined threshold.

In Example 2M8, the subject matter of any of Examples 2M1-2M7 can optionally include sampling the input voltage to obtain a first value of the input voltage at a first time and a second value of the input voltage at a second time, wherein the change in the input voltage is determined at least in part based on the first value and the second value.

In Example 2M9, the subject matter of Example 2M8 can optionally include performing a determination that a magnitude of a difference between the first value and the second value exceeds a magnitude of a predetermined threshold, wherein the first signal is produced, at least in part based on the determination.

In Example 2M10, the subject matter of any of Examples 2M1-2M9 can optionally include receiving, with a processor, the input voltage.

In Example 2M11, the subject matter of any of Examples 2M1-2M10 can optionally include receiving, with a voltage divider, a supply voltage to produce the input voltage.

Example 2C1 is a non-transitory, computer-readable medium encoded with instructions that, when executed by an electronic apparatus, cause the electronic apparatus to perform a method comprising: determining a change in an input voltage over time, at least in part based on a first frequency of a first clock; and producing a first signal, at least in part based on the magnitude of the change in the input voltage over time and a predetermined threshold.

In Example 2C2, the subject matter of Example 2C1 can optionally include the feature of the method further comprising: receiving a second signal indicating a rate of change of the input voltage over time, wherein the first signal is at least in part based on the second signal.

In Example 2C3, the subject matter of Example 2C2 can optionally include the feature that the second signal is a pulse-width signal proportional to the rate of change of the input voltage over time.

In Example 2C4, the subject matter of Example 2C3 can optionally include the feature of the method further comprising: sampling the pulse-width signal with a second clock having a second frequency higher than the first frequency.

In Example 2C5, the subject matter of Example 2C4 can optionally include the feature of the method further comprising: computing a duration that the pulse-width signal is asserted, at least in part based on the second frequency.

In Example 2C6, the subject matter of any of Examples 2C3-2C5 can optionally include the feature of the method further comprising: receiving the pulse-width signal from a sample-and-hold circuit.

In Example 2C7, the subject matter of any of Examples 2C1-2C6 can optionally include the feature of the method further comprising: dividing a reference voltage by the duration to produce the predetermined threshold.

In Example 2C8, the subject matter of any of Examples 2C1-2C7 can optionally include the feature of the method further comprising: sampling the input voltage to obtain a first value of the input voltage at a first time and a second value of the input voltage at a second time, wherein the change in the input voltage is determined at least in part based on the first value and the second value.

In Example 2C9, the subject matter of Example 2C8 can optionally include the feature of the method further comprising: performing a determination that a magnitude of a difference between the first value and the second value exceeds a magnitude of a predetermined threshold, wherein the first signal is produced, at least in part based on the determination.

In Example 2C10, the subject matter of any of Examples 2C4-2C9 can optionally include the feature that the electronic apparatus includes a processor that receives the input voltage.

In Example 2C11, the subject matter of any of Examples 2C1-2C10 can optionally include the feature of the method further comprising: receiving the input voltage from a voltage divider.

Example 2F1 is an apparatus, comprising: means for determining a change in an input voltage over time, at least in part based on a first frequency of a first clock; and means for producing a first signal, at least in part based on the magnitude of the change in the input voltage over time and a predetermined threshold.

In Example 2F2, the subject matter of Example 2F1 can optionally include means for generating a second signal indicating a rate of change of the input voltage over time, wherein the first signal is at least in part based on the second signal.

In Example 2F3, the subject matter of Example 2F2 can optionally include the feature that the second signal is a pulse-width signal proportional to the rate of change of the input voltage over time.

In Example 2F4, the subject matter of Example 2F3 can optionally include means for sampling the pulse-width signal with a second clock having a second frequency higher than the first frequency.

In Example 2F5, the subject matter of Example 2F4 can optionally include means for computing a duration that the pulse-width signal is asserted, at least in part based on the second frequency.

In Example 2F6, the subject matter of any of Examples 2F3-2F5 can optionally include means for producing the pulse-width signal, at least in part based on the input voltage.

In Example 2F7, the subject matter of any of Examples 2F1-2F6 can optionally include means for dividing a reference voltage by the duration to produce the predetermined threshold.

In Example 2F8, the subject matter of any of Examples 2F1-2F7 can optionally include means for sampling the input voltage to obtain a first value of the input voltage at a first time and a second value of the input voltage at a second time, wherein the change in the input voltage is determined at least in part based on the first value and the second value.

In Example 2F9, the subject matter of Example 2F8 can optionally include means for performing a determination that a magnitude of a difference between the first value and the second value exceeds a magnitude of a predetermined threshold, wherein the first signal is produced, at least in part based on the determination.

In Example 2F10, the subject matter of any of Examples 2F1-2F9 can optionally include the feature that means for receiving the input voltage.

In Example 2F11, the subject matter of any of Examples 2F1-2F10 can optionally include means for receiving a supply voltage to produce the input voltage.

Example 2S1 is system, comprising: a first circuit to generate a first clock having a first frequency; and logic to determine a change in an input voltage over time, at least in part based on the first frequency, and to produce a first signal, at least in part based on the magnitude of the change in the input voltage over time and a predetermined threshold.

In Example 2S2, the subject matter of Example 2S1 can optionally include the feature that the logic further is to generate a second signal indicating a rate of change of the input voltage over time, and the first signal is at least in part based on the second signal.

In Example 2S3, the subject matter of Example 2S2 can optionally include the feature that the second signal is a pulse-width signal proportional to the rate of change of the input voltage over time.

In Example 2S4, the subject matter of Example 2S3 can optionally include a second circuit to generate a second clock having a second frequency higher than the first frequency, wherein the logic further is to sample the pulse-width signal with the second clock.

In Example 2S5, the subject matter of Example 2S4 can optionally include the feature that the logic further is to compute a duration that the pulse-width signal is asserted, at least in part based on the second frequency.

In Example 2S6, the subject matter of any of Examples 2S3-2S5 can optionally include a sample-and-hold circuit to produce the pulse-width signal, at least in part based on the input voltage.

In Example 2S7, the subject matter of any of Examples 2S1-2S6 can optionally include the feature that the logic further is to divide a reference voltage by the duration to produce the predetermined threshold.

In Example 2S8, the subject matter of any of Examples 2S1-2S7 can optionally include the feature that the logic further is to sample the input voltage to obtain a first value of the input voltage at a first time and a second value of the input voltage at a second time, and the change in the input voltage is determined at least in part based on the first value and the second value.

In Example 2S9, the subject matter of Example 2S8 can optionally include the feature that the logic further is to perform a determination that a magnitude of a difference between the first value and the second value exceeds a magnitude of a predetermined threshold, and the first signal is produced, at least in part based on the determination.

In Example 2S10, the subject matter of any of Examples 2S1-2S9 can optionally include a processor that receives the input voltage.

In Example 2S11, the subject matter of any of Examples 2S1-2S10 can optionally include a voltage divider that receives a supply voltage and produces the input voltage.

We claim:

1. An apparatus, comprising:
a circuit to generate a clock having a period with a duty cycle less than or equal to 90%; and
logic to determine a difference in an input voltage between a first time and a second time, at least in part based on the duty cycle of the clock, and to produce a first signal, at least in part based on the difference in the input voltage and a first predetermined threshold.

2. The apparatus of claim 1, wherein the logic further is to determine a first value of the input voltage at a first time, at least in part based on the duty cycle of the clock.

3. The apparatus of claim 2, wherein the logic further is to determine a second value of the input voltage at a second time, at least in part based on a remainder of the period of the clock.

4. The apparatus of claim 3, wherein the difference is determined, at least in part based on a difference between the second value and the first value.

5. The apparatus of claim 1, wherein the logic further is to produce the first signal, at least in part based on a determination that the magnitude of the difference in the input voltage exceeds the magnitude of the first predetermined threshold for a predetermined number of periods of the clock, and the predetermined number of periods is greater than 1.

6. The apparatus of claim 5, wherein the first signal throttles a processor.

7. The apparatus of claim 6, further comprising:
the processor, wherein the processor receives the input voltage and the first signal.

8. The apparatus of claim 1, further comprising:
a level comparator to produce a second signal indicating whether the sampled voltage is less than a reference voltage.

9. The apparatus of claim 8, wherein the logic produces the first signal, at least in part based on the second signal.

10. The apparatus of claim 1, further comprising:
a sample-and-hold circuit that samples the input voltage.

11. The apparatus of claim 1, further comprising:
a voltage divider that receives a supply voltage and produces the input voltage, wherein the input voltage is at least in part based on the divided voltage.

12. A method implemented by an apparatus, the method comprising:
determining a difference in an input voltage between a first time and a second time, at least in part based on a duty cycle of a clock, the duty cycle being less than or equal to 90% of a period of the clock; and
producing a first signal, at least in part based on the difference in the input voltage and a first predetermined threshold.

13. The method of claim 12, further comprising:
determining a first value of the input voltage at a first time, at least in part based on the duty cycle of the clock; and
determining a second value of the input voltage at a second time, at least in part based on a remainder of the period of the clock, wherein the difference is determined, at least in part based on a difference between the second value and the first value.

14. The method of claim 13, further comprising:
producing the first signal, at least in part based on a determination that the magnitude of the difference in the input voltage exceeds the magnitude of the first predetermined threshold for a predetermined number of periods of the clock, wherein the predetermined number of periods is greater than 1.

15. The method of claim 14, wherein the apparatus includes a processor that receives the input voltage and the first signal, and the first signal throttles the processor.

16. The method of claim 12, further comprising:
producing, with a level comparator, a second signal indicating whether the sampled voltage is less than a reference voltage, wherein the producing the first signal produces the first signal, at least in part based on the second signal.

17. A non-transitory, computer-readable medium encoded with instructions that, when executed by an electronic apparatus, cause the electronic apparatus to perform a method comprising:
determining a difference in an input voltage between a first time and a second time, at least in part based on a duty cycle of a clock, the duty cycle being less than or equal to 90% of a period of the clock; and
producing a first signal, at least in part based on the difference in the input voltage and a first predetermined threshold.

18. The medium of claim 17, the method further comprising:
determining a first value of the input voltage at a first time, at least in part based on the duty cycle of the clock; and
determining a second value of the input voltage at a second time, at least in part based on a remainder of the period of the clock, wherein the difference is determined, at least in part based on a difference between the second value and the first value.

19. The medium of claim 17, the method further comprising:
producing the first signal, at least in part based on a determination that the magnitude of the difference in the input voltage exceeds the magnitude of the first predetermined threshold for a predetermined number of periods of the clock, wherein the predetermined number of periods is greater than 1, the first signal throttles a processor, the electronic apparatus includes the processor, and the processor receives the input voltage and the first signal.

20. The medium of claim 17, the method further comprising:
receiving, from a level comparator, a second signal indicating whether the sampled voltage is less than a reference voltage, wherein the producing the first signal produces the first signal, at least in part based on the second signal.
